(19) United States
(12) Patent Application Publication
(10) Pub. No.: US 2025/0194012 A1
(43) Pub. Date: Jun. 12, 2025

(54) PRINTED WIRING BOARD, ELECTRONIC MODULE, ELECTRONIC EQUIPMENT AND VIDEO DISPLAYING APPARATUS

(71) Applicant: CANON KABUSHIKI KAISHA, Tokyo (JP)

(72) Inventors: SHOJI MATSUMOTO, Kanagawa (JP); MASANORI KIKUCHI, Kanagawa (JP)

(21) Appl. No.: 18/959,004

(22) Filed: Nov. 25, 2024

(30) Foreign Application Priority Data
Dec. 7, 2023 (JP) 2023-207282

(51) Int. Cl. H05K 1/11; H05K 1/02

(52) U.S. Cl. CPC H05K 1/116; H05K 1/0218; H05K 2201/09518; H05K 2201/096; H05K 2201/10128

(57) ABSTRACT

A printed wiring board includes: a first layer including conductor layers; a second layer the first layer is stacked on; first vias formed in the first layer; first pads formed corresponding to the conductor layers in the first layer and connected to the first vias; ground patterns formed in the conductor layers and having openings surrounding the first pads; a second via formed in the second layer; and a second pad formed on a surface of the second layer on a side of the first layer and connected to the first and second vias, wherein the first pads and the second pad overlap in a plan view, wherein the diameters of the openings in the ground patterns are larger than that of the second pad, and wherein the diameter of the opening farthest from the second layer is smaller than that of the opening closest to the second layer.

### BACKGROUND

### Field

The present disclosure relates to a printed wiring board, an electronic module, electronic equipment, and a video displaying apparatus.

### Description of the Related Art

Due to the demand for miniaturization of electronic equipment, there has been an increase in the adoption of build-up substrates, which enable high-density wiring and placing vias in printed wiring boards mounted in electronic equipment. The build-up substrate includes a core layer in which vias are used to penetrate the core portion of the substrate, and build-up layers formed by building up conductors one by one outside the core layer. The via used in the build-up layer is smaller in diameter and has a smaller parasitic component than the via that penetrates the core layer, which is also advantageous in that it does not degrade the waveform quality of high-speed transmission signals.

In recent years, data communications using digital signals with transmission speeds exceeding 10 Gbps have been conducted between two semiconductor devices mounted on a printed circuit board. In order to ensure the waveform quality of the transmission signals, characteristic impedance matching of transmission lines formed by wirings and vias on the printed circuit board is required. In addition, the higher the speed of the transmission signal, the more the impedance mismatch of minute portions that is negligible at low speed becomes apparent, and as a result, the waveform quality of the transmission signal may deteriorate. Therefore, impedance matching is required even in the via of the build-up substrate, which has been advantageous in high-speed transmission. Japanese Patent Application Laid-Open No. 2021-158131 and Japanese Patent Application Laid-Open No. 2015-154145 disclose an impedance matching method for a build-up substrate and a via structure that suppresses reflection when the characteristic impedances of signal wirings that are connected to signal vias are different.

In Japanese Patent Application Laid-Open No. 2021-158131, in order to suppress the parasitic capacitance due to the overlap between the pad of a via of a build-up layer and a ground of an inner layer thus to achieve the impedance matching, the open diameter of a ground around an inner layer via pad and the open diameter of a ground around a pad for the signal of a surface layer are set to the same size. Japanese Patent Application Laid-Open No. 2015-154145, when the characteristic impedance of signal wirings connected to a signal via is different, the impedance of the via is gradually changed to buffer the characteristic impedance mismatch between the signal wirings.

In a case of a higher density design, in the build-up substrate, a via penetrating the core layer and a via of the build-up layer may be overlapped to be arranged in a plan view. In the case of this configuration, it is difficult to suppress the impedance mismatch caused by the parasitic capacitance between the via of the build-up layer and the via of the core layer in the techniques disclosed in Japanese Patent Application Laid-Open No. 2021-158131 and Japanese Patent Application Laid-Open No. 2015-154145.

### SUMMARY

An object of the present disclosure is to provide a printed wiring board that can improve the quality of the waveform of a transmission signal in a build-up substrate.

According to one aspect of the present disclosure, there is provided a printed wiring board including: a first layer including a plurality of stacked conductor layers; a second layer on which the first layer is stacked; a plurality of first vias formed in the first layer; a plurality of first pads formed corresponding to the plurality of conductor layers in the first layer and connected to the first vias, respectively; a plurality of ground patterns formed in the plurality of conductor layers and each having an opening surrounding the first pad; a second via formed in the second layer; and a second pad formed on a surface of the second layer on a side of the first layer and connected to the first via and the second via, wherein the plurality of first pads and the second pad overlap in a plan view viewed in a direction in which the first layer and the second layer are stacked, wherein the diameters of a plurality of the openings in the plurality of ground patterns are larger than the diameter of the second pad, and wherein the diameter of the opening farthest from the second layer is smaller than the diameter of the opening closest to the second layer.

Further features of the present invention will become apparent from the following description of exemplary embodiments with reference to the attached drawings.

### BRIEF DESCRIPTION OF THE DRAWINGS

FIG. 1A is a schematic diagram illustrating a printed wiring board according to a first embodiment.

FIG. 1B is a schematic diagram illustrating the printed wiring board according to the first embodiment.

FIG. 1C is a schematic diagram illustrating the printed wiring board according to the first embodiment.

FIG. 1D is a schematic diagram illustrating the printed wiring board according to the first embodiment.

FIG. 1E is a schematic diagram illustrating the printed wiring board according to the first embodiment.

FIG. 1F is a schematic diagram illustrating the printed wiring board according to the first embodiment.

FIG. 1G is a schematic diagram illustrating the printed wiring board according to the first embodiment.

FIG. 1H is a schematic diagram illustrating a modification of the printed wiring board according to the first embodiment.

FIG. 2 is a graph showing the results of TDR simulations performed for examples and comparative examples.

FIG. 3A is a side view illustrating a head-mounted display as an example of electronic equipment according to a second embodiment.

FIG. 3B is a front view illustrating the head-mounted display as the example of the electronic equipment according to the second embodiment.

### DESCRIPTION OF THE EMBODIMENTS

### First Embodiment

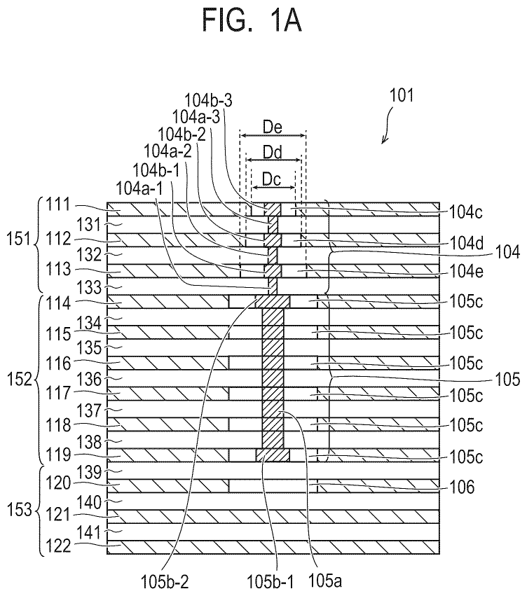

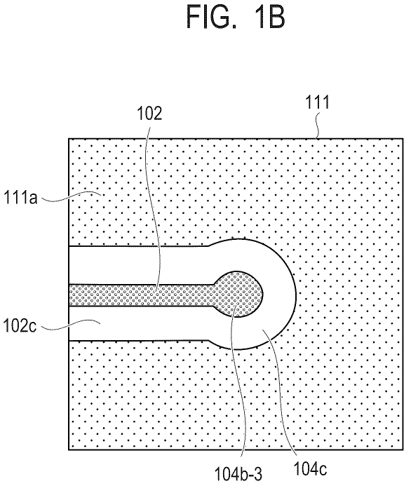

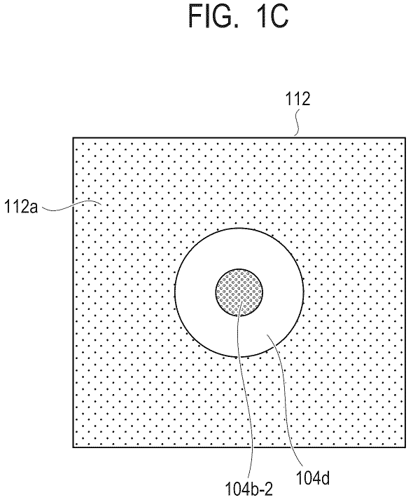

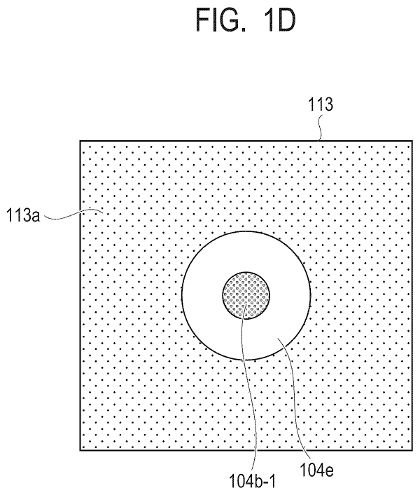

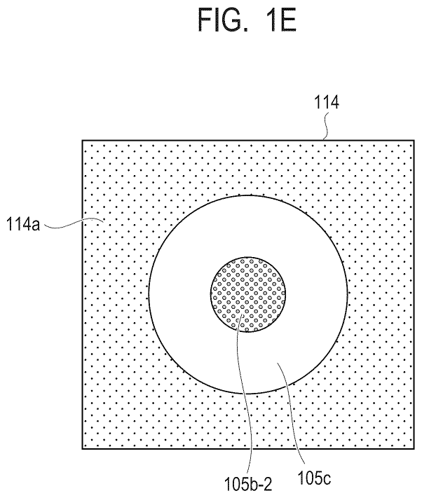

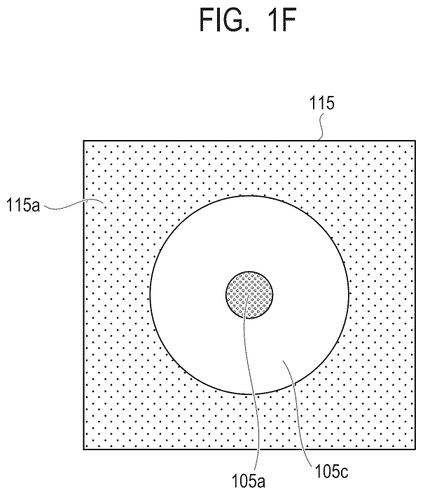

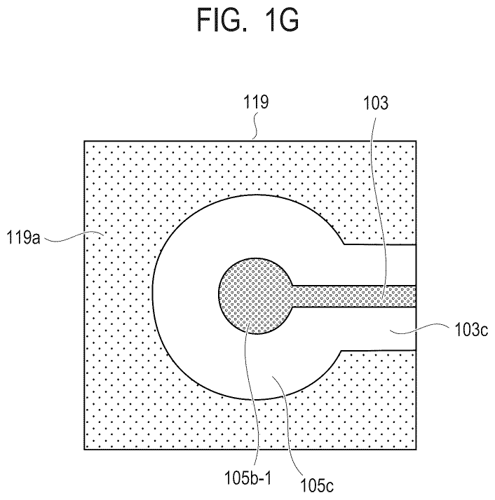

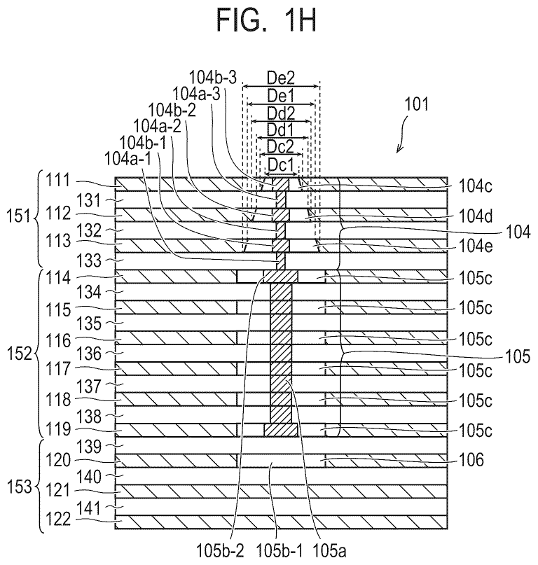

A printed circuit board according to a first embodiment of the present disclosure will be described with reference to FIG. 1A to FIG. 1H. FIG. 1A is a cross-sectional view illustrating a printed wiring board 101 according to the present embodiment. FIG. 1B is a plan view illustrating a conductor layer 111 of a build-up layer 151 in the printed wiring board 101. FIG. 1C is a plan view illustrating a conductor layer 112 of the build-up layer 151 in the printed wiring board 101. FIG. 1D is a plan view illustrating a conductor layer 113 of the build-up layer 151 in the printed wiring board 101. FIG. 1E is a plan view illustrating a conductor layer 114 of a core layer 152 in the printed wiring board 101. FIG. 1F is a plan view illustrating a conductor layer 115 of the core layer 152 in the printed wiring board 101. FIG. 1G is a plan view illustrating a conductor layer 119 of the core layer 152 in the printed wiring board 101. FIG. 1B to FIG. 1G are plan views in a plan view viewed in a stacking direction of each conductor layer which is a direction perpendicular to the board surface of the printed wiring board 101, that is, a direction in which the build-up layers 151 and 153 and the core layer 152 are stacked. FIG. 1H is a cross-sectional view illustrating a modification of the printed wiring board 101 according to the present embodiment.

As illustrated in FIG. 1A to FIG. 1G, the printed wiring board 101 is a build-up substrate that includes 12 conductor layers 111 to 122. The conductor layers 111 to 122 are stacked between one surface and the other surface of the printed wiring board 101 with insulating layers 131 to 141 therebetween.

Among the 12 layers, the conductor layers 111, 112, and 113 of the first layer to the third layer constitute a build-up layer 151. The conductor layers 114, 115, 116, 117, 118, and 119 of the fourth layer to the ninth layer constitute a core layer 152. The conductor layers 120, 121, and 122 of the tenth layer to the twelfth layers constitute a build-up layer 153. The build-up layer 151 is stacked on one surface of the core layer 152. The build-up layer 153 is stacked on the other surface of the core layer 152.

The conductor layers 111 to 122 are composed of a conductor made of copper foil or the like. The insulating layer 131 is formed between the conductor layer 111 and the conductor layer 112. The insulating layer 132 is formed between the conductor layer 112 and the conductor layer 113. The insulating layer 133 is formed between the conductor layer 113 and the conductor layer 114. The insulating layer 134 is formed between the conductor layer 114 and the conductor layer 115. The insulating layer 135 is formed between the conductor layer 115 and the conductor layer 116. The insulating layer 136 is formed between the conductor layer 116 and the conductor layer 117. The insulating layer 137 is formed between the conductor layer 117 and the conductor layer 118. The insulating layer 138 is formed between the conductor layer 118 and the conductor layer 119. The insulating layer 139 is formed between the conductor layer 119 and the conductor layer 120. The insulating layer 140 is formed between the conductor layer 120 and the conductor layer 121. The insulating layer 141 is formed between the conductor layer 121 and the conductor layer 122. The insulating layers 131 to 141 interposed between the conductor layers 111 to 122 are composed of an insulator such as resin by prepreg or the like. A resist layer (not illustrated) is formed as a protective layer on each of the outer surface of the conductor layer 111 of the first layer, which is the outermost layer of the build-up layer 151, and the outer surface of the conductor layer 122 of the twelfth layer, which is the outermost layer of the build-up layer 153.

The printed wiring board 101 further includes wirings 102 and 103, a build-up via 104, and a through via 105. The build-up via 104 is a via formed in the build-up layer 151 including conductor layers 111, 112, and 113 of the first layer to the third layer. The through via 105 is a via formed in the core layer 152 including conductor layers 114, 115, 116, 117, 118, and 119 of the fourth layer to the ninth layer.

The wiring 102 is formed in the conductor layer 111 of the first layer. In the conductor layer 111, a ground pattern 111a is formed on both sides of the wiring 102. On the other hand, the wiring 103 is formed in the conductor layer 119 of the ninth layer. In the conductor layer 119, a ground pattern 119a is formed on both sides of the wiring 103. The wiring 102 and the wiring 103 are electrically connected to each other via the build-up via 104 and the through via 105. Note that the wirings 102 and 103 are not illustrated in FIG. 1A. The wirings 102 and 103 are signal wirings for transmitting a high-speed signal such as a digital signal having a transmission speed exceeding, for example, 10 Gbps, or the like.

The build-up via 104 includes three levels of vias 104a-1, 104a-2, and 104a-3, and via pads 104b-1, 104b-2, and 104b-3, which are stacked to form the build-up via 104. The via 104a-1, the via pad 104b-2, the via 104a-2, the via pad 104b-2, the via 104a-3, and via pad 104b-3 are stacked in this order from the side of the inner layer of the printed wiring board 101 to the side of one surface.

The via 104a-1 of the first level is a via by a hole formed in the conductor layer 113 and the insulating layer 133 between the conductor layer 113 and the conductor layer 114. The via 104a-1 is composed of, for example, a conductor formed by copper plating or the like formed on the wall surface of the hole or further composed of a conductor formed by copper plating or the like filled in the hole. The via 104a-1 has a circular planar shape in a plan view viewed in a direction perpendicular to the board surface of the printed wiring board 101.

In the same layer as the conductor layer 113, the via pad 104b-1 arranged so as to overlap the via 104a-1 in a plan view viewed in a direction perpendicular to the board surface of the printed wiring board 101 is formed corresponding to the conductor layer 113. The via pad 104b-1 is formed of a conductor such as copper foil or the like. The via pad 104b-1 is a pad having a circular planar shape larger in diameter than the via 104a-1 in the plan view. The via pad 104b-1 is connected to the via 104a-1.

A ground pattern 113a is formed in the conductor layer 113. A ground clearance 104e is formed in the ground pattern 113a. The ground clearance 104e is an opening where there is no conductor in the conductor layer 113. The ground clearance 104e has a circular planar shape surrounding the via pad 104b-1 in a plan view viewed in a direction perpendicular to the board surface of the printed wiring board 101. The build-up via 104 including the via 104a-1 and the via pad 104b-1 is formed inside the ground clearance 104e.

The via 104a-2 of the second level is a via by a hole formed in the conductor layer 112 and the insulating layer 132 between the conductor layer 112 and the conductor layer 113. The via 104a-2 is composed of, for example, a conductor formed by copper plating or the like formed on the wall surface of the hole in the same manner as the via 104a-1, or further composed of a conductor formed by copper plating or the like filled in the hole. The via 104a-2 has a circular planar shape in a plan view viewed in a direction perpendicular to the board surface of the printed wiring board 101. The via 104a-2 is arranged so as to overlap the via pad 104b-1 in the plan view and is connected to the via pad 104b-1.

In the same layer as the conductor layer 112, the via pad 104b-2 arranged so as to overlap the via 104a-2 in a plan view viewed in a direction perpendicular to the board surface of the printed wiring board 101 is formed corresponding to the conductor layer 112. The via pad 104b-2 is formed of a conductor such as copper foil or the like. The via pad 104b-2 is a pad having a circular planar shape larger in diameter than the via 104a-2 in the plan view. The via pad 104b-2 is connected to the via 104a-2. In the plan view, the diameter of the via 104a-2 is equal to the diameter of the via 104a-1, and the diameter of the via pad 104b-2 is equal to the diameter of the via pad 104b-1. Note that, in the plan view, the diameter of the via 104a-2 may be different from the diameter of the via 104a-1, and the diameter of the via pad 104b-2 may be different from the diameter of the via pad 104b-1.

A ground pattern 112a is formed in the conductor layer 112. A ground clearance 104d is formed in the ground pattern 112a. The ground clearance 104d is an opening where there is no conductor in the conductor layer 112. The ground clearance 104d has a circular planar shape surrounding the via pad 104b-2 in a plan view viewed in a direction perpendicular to the board surface of the printed wiring board 101. The build-up via 104 including the via 104a-2 and the via pad 104b-2 is formed inside the ground clearance 104d.

The via 104a-3 of the third level is a via by a hole formed in the conductor layer 111 and the insulating layer 131 between the conductor layer 111 and the conductor layer 112. The via 104a-3 is composed of, for example, a conductor formed by copper plating or the like formed on the wall surface of the hole in the same manner as the via 104a-1 and the via 104a-2, or further composed of a conductor formed by copper plating or the like filled in the hole. The via 104a-3 has a circular planar shape in a plan view viewed in a direction perpendicular to the board surface of the printed wiring board 101. The via 104a-3 is arranged so as to overlap the via pad 104b-2 in the plan view and is connected to the via pad 104b-2.

In the same layer as the conductor layer 111, the via pad 104b-3 arranged so as to overlap the via 104a-3 in a plan view viewed in a direction perpendicular to the board surface of the printed wiring board 101 is formed corresponding to the conductor layer 111. The via pad 104b-3 is formed of a conductor such as copper foil or the like. The via pad 104b-3 is a pad having a circular planar shape larger in diameter than the via 104a-3 in the plan view. The via pad 104b-3 is connected to the via 104a-3. In the plan view, the diameter of the via 104a-3 is equal to the diameter of the via 104a-2, and the diameter of the via pad 104b-3 is equal to the diameter of the via pad 104b-2. Note that, in the plan view, the diameter of the via 104a-3 may be different from the diameter of the via 104a-2, and the diameter of the via pad 104b-3 may be different from the diameter of the via pad 104b-2.

A ground pattern 111a is formed in the conductor layer 111. Ground clearances 102c and 104c are formed in the ground pattern 111a. The ground clearances 102c and 104c are openings where there is no conductor in the conductor layer 111. The ground clearance 102c has a belt-like planar shape surrounding the wiring 102 in a plan view viewed in a direction perpendicular to the board surface of the printed wiring board 101. The ground clearance 104c has a circular planar shape surrounding the via pad 104b-3 in the plan view. The ground clearances 102c and 104c are connected so as to surround the interconnected wiring 102 and the via pad 104b-3. The build-up via 104 including the via 104a-3 and the via pad 104b-3 is formed inside the ground clearance 104c.

Note that the via 104a-1, 104a-2, and 104a-3 may have a planar shape other than a circle in a plan view viewed in a direction perpendicular to the board surface of the printed wiring board 101. In this case, the diameter of the via 104a-1, 104a-2, and 104a-3 is a diameter that is the maximum value of the distance between two points in the planar shape.

In addition, the via pads 104b-1, 104b-2, and 104b-3 may also have a planar shape other than a circle in the plan view. In this case, the diameter of the via pads 104b-1, 104b-2, and 104b-3 is a diameter that is the maximum value of the distance between two points in the planar shape.

In addition, the ground clearances 104c, 104d, and 104e may have a planar shape other than a circle in a plan view viewed in a direction perpendicular to the board surface of the printed wiring board 101. In this case, the diameter of the ground clearances 104c, 104d, and 104e is a diameter that is the maximum value of the distance between two points in the planar shape.

The above-described three vias 104a-1, 104a-2, and 104a-3 and the three via pads 104b-1, 104b-2, and 104b-3 are arranged so as to overlap in a plan view of the printed wiring board 101 in a direction perpendicular to the board surface of the printed wiring board 101. The wiring 102 is connected to the via pad 104b-3 formed in the same layer as the conductor layer 111 corresponding to the conductor layer 111. When the diameter of the ground clearance 104c is Dc, the diameter of the ground clearance 104d is Dd, and the diameter of the ground clearance 104e is De, the diameters Dc, Dd, and De have the following large and small relationships, and the diameter De is the largest. That is, the diameters Dc, Dd, and De of the ground clearances 104c, 104d, and 104e are smaller as the ground clearance is farther from the core layer 152.

$$Dc < Dd < De$$

Note that the diameters Dc, Dd, and De may be extended in a stepwise manner in the direction from the build-up layer 151 toward the core layer 152, or the diameters Dc, Dd, and De may be respectively extended in a tapered manner as illustrated in FIG. 1H. In the case illustrated in FIG. 1H, the ground clearance 104c is formed so that the diameter Dc is tapered from the minimum value Dc1 to the maximum value Dc2 in the direction from the build-up layer 151 toward the core layer 152. The ground clearance 104d is formed so that the diameter Dd is tapered from the minimum value Dd1 to the maximum value Dd2 in the direction from the build-up layer 151 toward the core layer 152. The ground clearance 104e is formed so that the diameter De is tapered from the minimum value De1 to the maximum value De2 in the direction from the build-up layer 151 toward the core layer 152.

The relationship between the diameters Dc, Dd and De is not limited to the above relationship, and the diameters of two of these diameters Dc, Dd and De may be equal to each other. Specifically, the diameter Dd and the diameter De may be equal, or the diameter Dc and the diameter Dd may be equal. That is, the diameters Dc, Dd, and De may have one of the following two large and small relationships, and the diameter De may be the largest.

$$Dc < Dd = De$$

$$Dc = Dd < De$$

Note that, when the diameters Dc, Dd, and De are tapered as illustrated in FIG. 1H, the respective minimum and maximum values can be used to express the large and small relationship by the following expression.

$$Dc 1 < Dc 2 \leq Dd 1 < Dd 2 \leq De 1 < De 2$$

Of the diameters Dc, Dd, and De of the ground clearances 104c, 104d, and 104e, the diameter Dc of the ground clearance 104c farthest from the core layer 152 is preferably the smallest. The via pad 104b-3 surrounded by the ground clearance 104c farthest from the core layer 152 is located in the outermost layer of the build-up layer 151. Therefore, by minimizing the diameter Dc of the ground clearance 104c, the outermost layer of the build-up layer 151 can have a large area where components can be arranged.

The through via 105 includes a via 105a and via pads 105b-1 and 105b-2. The via 105a is a via formed by a through hole formed in the insulating layers 134 to 138 of the core layer 152 including the conductor layer 114 to the conductor layer 119. The via pad 105b-2 is formed on the surface of the core layer 152 on the side of the build-up layer 151. That is, the via pad 105b-2 is formed in the same layer as the conductor layer 114, which is the outermost layer of the core layer 152 on the side of the conductor layer 113, corresponding to the conductor layer 114. The via pad 105b-1 is formed on the surface of the core layer 152 on the side of the build-up layer 153, which is the opposite side to the build-up layer 151. That is, the via pad 105b-1 is formed in the same layer as the conductor layer 119, which is the outermost layer of the core layer 152 on the conductor layer 120, corresponding to the conductor layer 119. The via pads 105b-1 and 105b-3 are respectively connected to the via 105a.

The via 105a is composed of, for example, a conductor formed by copper plating or the like formed on the wall surface of the through hole, and an insulator such as resin is filled in the through hole where the conductor is formed. The via 105a has a circular planar shape in a plan view viewed in a direction perpendicular to the board surface of the printed wiring board 101.

The via pad 105b-1 is arranged so as to overlap with the via 105a in a plan view viewed in a direction perpendicular to the board surface of the printed wiring board 101. The via pad 105b-1 is composed of a conductor such as copper foil or the like. The via pad 105b-1 is a pad having a circular planar shape larger in diameter than the via 105a in the plan view.

The via pad 105b-2 is arranged so as to overlap the via 105a in a plan view viewed in a direction perpendicular to the board surface of the printed wiring board 101. The via pad 105b-2 is composed of a conductor such as copper foil or the like. The via pad 105b-2 is a pad having a circular planar shape larger in diameter than the via 105a in the plan view. In the plan view, the diameter of the via pad 105b-2 is equal to the diameter of the via pad 105b-1. Note that, in the plan view, the diameter of the via pad 105b-2 may be different from the diameter of the via pad 105b-1.

The diameter of the via 105a formed in the core layer 152 as described above is larger than the diameter of the vias 104a-1, 104a-2, and 104a-3 formed in the build-up layer 151. The diameters of the via pads 105b-1 and 105b-2 formed in the core layer 152 are larger than the diameters of the via pads 104b-1, 104b-2, and 104b-3 formed in the build-up layer 151.

Ground patterns 114a to 119a are formed in the conductor layers 114 to 119, respectively. Ground clearance 105c is formed in each of the ground patterns 114a to 119a. Ground clearance 103c is further formed in the ground pattern 119a. Each of the ground clearances 103c and 105c is an opening where no conductor is formed in the corresponding conductor layers 114 to 119. The ground clearance 105c of the ground pattern 114a has a circular planar shape surrounding the via pad 105b-2 in a plan view viewed in a direction perpendicular to the board surface of the printed wiring board 101. The ground clearance 105c of the ground patterns 115a to 118a has a circular planar shape surrounding the via 105a in the plan view. The ground clearance 103c of the ground pattern 119a has a belt-like planar shape surrounding the wiring 103 in the plan view. The ground clearance 105c of the ground pattern 119a has a circular planar shape surrounding the via pad 105b-1 in the plan view. The ground clearances 103c and 105c of the ground pattern 119a are connected so as to surround the interconnected wiring 103 and the via pad 105b-1. Thus, the through via 105 is formed inside the ground clearances 105c of the respective ground patterns 114a to 119a in the core layer 152. The diameters of the ground clearances 105c of the ground patterns 114a to 119a are equal to each other. Note that the diameters of the ground clearances 105c of the ground patterns 114a to 119a may be different from each other.

Note that the via 105a may have a planar shape other than a circle in a plan view viewed in a direction perpendicular to the board surface of the printed wiring board 101. In this case, the diameter of the via 105a is a diameter that is the maximum value of the distance between two points in the planar shape.

Further, the via pads 105b-1 and 105b-2 may have a planar shape other than a circle in the plan view. In this case, the diameter of the via pads 105b-1 and 105b-2 is a diameter that is the maximum value of the distance between two points in the planar shape.

The ground clearance 105c may have a planar shape other than a circle in a plan view viewed in a direction perpendicular to the board surface of the printed wiring board 101. In this case, the diameter of the ground clearance 105c is a diameter that is the maximum value of the distance between two points in the planar shape.

The build-up via 104 and the through via 105 are arranged so as to overlap in a plan view viewed in a direction perpendicular to the board surface of the printed wiring board 101. That is, the vias 104a-1, 104a-2, and 104a-3, the via pads 104b-1, 104b-2, and 104b-3, the via 105a, and the via pads 105b-1 and 1-5b-2 are arranged so as to overlap in the plan view. The wiring 103 provided in the conductor layer 119 is connected to the via pad 105b-1 formed in the same layer as the conductor layer 119 corresponding to the conductor layer 119.

Of the conductor layers 120 to 122 included in the build-up layer 153 on the opposite side of the build-up layer 151 in which the build-up via 104 is formed, a ground clearance 106 is formed in the conductor layer 120 on the side closest to the core layer 152. The ground clearance 106 has a circular planar shape in a plan view viewed in a direction perpendicular to the board surface of the printed wiring board 101. The diameter of the ground clearance 106 is equal to the diameter of the ground clearance 105c of the conductor layer 119. The ground clearance 106 is arranged so as to overlap the ground clearance 105c of the ground pattern 119a in the plan view. Note that the diameter of the ground clearance 106 may be different from the diameter of the ground clearance 105c of the ground pattern 119a.

Note that the ground clearance 106 may have a planar shape other than a circle in a plan view viewed in a direction perpendicular to the board surface of the printed wiring board 101. In this case, the diameter of the ground clearance 105c is a diameter that is the maximum value of the distance between two points in the planar shape.

When the diameter of the via pads 105b-1 and 105b-2 is Dp and this diameter Dp is compared with the diameters Dc, Dd, and De of the ground clearances 104c, 104d, and 104e in which the build-up via 104 is formed, these have the following large and small relationships.
Dp<Dc
Dp<Dd
Dp<De

As described above, in the present embodiment, the diameters Dc, Dd, and De of the ground clearances 104c, 104d, and 104e are larger than the diameter Dp of the via pad 105b-2 of the same layer as the conductor layer 114. Thus, the parasitic capacitance generated between the through via 105 of the core layer 152 and the build-up via 104 of the build-up layer 151 can be reduced, and the impedance mismatch due to the parasitic capacitance can be suppressed.

Furthermore, in the present embodiment, among the ground clearances 104c, 104d, and 104e, the diameter Dc of the ground clearance 104c farthest from the core layer 152 is smaller than the diameter Dc of the ground clearance 104e closest to the core layer 152. This can suppress an increase in the characteristic impedance of the wiring 102 wired within the ground clearance 104c.

Thus, according to the present embodiment, the quality of the waveform of the transmission signal in the printed wiring board 101, which is a build-up substrate, can be improved.

Note that, in the above embodiment, the case where the build-up layer 151 has three conductive layers 111 to 113, the core layer 152 has six conductive layers 114 to 119, and the build-up layer 153 has three conductive layers 120 to 122 is described as an example, but the conductive layers are not limited to these. Each of the build-up layer 151, the core layer 152, and the build-up layer 153 may have a plurality of conductor layers according to the design.

When each of the above layers has a plurality of conductor layers, the diameters of the plurality of ground clearances formed in the plurality of ground patterns in the plurality of conductor layers of the build-up layer 151 should be larger than the diameter of the via pad 105b-2 of the core layer 152. Also, among the plurality of ground clearances in the build-up layer 151, the diameter of the ground clearance farthest from the core layer 152 should be smaller than the diameter of the ground clearance closest to the core layer 152.

Also, in this case, among the plurality of ground clearances in the build-up layer 151, the diameter of the ground clearance farthest from the core layer 152 may be the smallest. Also, in this case, the diameter of the plurality of ground clearances in the build-up layer 151 may be smaller as the ground clearance farther from the core layer 152.

### EXAMPLES

The suppression effect of the impedance mismatch was confirmed by simulation for printed wiring boards of examples and comparative examples in which specific numerical values were set for the printed wiring board 101 according to the first embodiment.

### Example 1

In Example 1, the thicknesses of the conductor layers 111, 114, 119, and 122 were 36 μm, respectively. The thicknesses of the conductor layers 112, 113, 120, and 121 were 26 μm, respectively. The thicknesses of the conductor layers 115, 116, 117, and 118 were 14 μm, respectively. The thicknesses of the insulating layers 131, 132, and 133 between the conductor layer 111 and the conductor layer 112, between the conductor layer 112 and the conductor layer 113, and between the conductor layer 113 and the conductor layer 114 were 80 μm, respectively. The thicknesses of the insulating layers 139, 140, and 141 between the conductor layer 119 and the conductor layer 120, between the conductor layer 120 and the conductor layer 121, and between the conductor layer 121 and the conductor layer 122 were also 80 μm, respectively. The thicknesses of the insulating layers 134 and 138 between the conductor layer 114 and the conductor layer 115 and between the conductor layer 118 and the conductor layer 119 were 120 μm, respectively. The thicknesses of the insulating layers 135 and 137 between the conductor layer 115 and the conductor layer 116 and between the conductor layer 117 and the conductor layer 118 were 200 μm, respectively. The thickness of the insulating layer 136 between the conductor layer 116 and the conductor layer 117 was 160 μm. The thicknesses of solder resist layers formed outside the conductor layer 111 and outside the conductor layer 122 were 30 μm, respectively.

The diameters of the holes of the vias 104a-1, 104a-2, and 104a-3 were 150 μm, respectively. The diameters of the via pads 104b-1, 104b-2, and 104b-3 were 275 μm, respectively. The diameter Dc of the ground clearance 104c of the conductor layer 111 was 675 μm. The diameter Dd of the ground clearance 104d of the conductor layer 112 was 775 μm. The diameter De of the ground clearance 104e of the conductor layer 113 was 875 μm.

The diameter of the hole of the via 105a was 300 μm. The diameters of via pads 105b-1 and 105b-2 were 500 μm, respectively. The diameters of the ground clearances 105c of the conductor layers 114 to 120 were 1300 μm.

The width of the wiring 102 was 100 μm. The gaps between wiring 102 and the ground pattern on both sides of the wiring 102 were 250 μm, respectively. The width of the wiring 103 was 85 μm. The gaps between the wiring 103 and the ground patterns on both sides of the wiring 103 were 307.5 μm, respectively.

The time domain reflectometry (TDR) characteristics of the printed wiring board 101 of Example 1 were analyzed by simulation. In the simulation, a step pulse signal was input to the wiring 102, and the characteristic impedance was analyzed from the waveform of the signal passing through the build-up via 104, the through via 105, and the wiring 103. The transmission line was modeled using HFSS of ANSYS, Inc. The TDR characteristics were analyzed using HSPICE of Synopsys, Inc.

Similar to the printed wiring board 101 of Example 1, The TDR characteristics of the printed circuit boards of Comparative Examples 1 and 2 were also analyzed by simulation. In Comparative Example 1, the ground clearances 104c, 104d, and 104e of Example 1 were all made to have the same diameter of 475 μm. In Comparative Example 2, the ground clearances 104c, 104d, and 104e of Example 1 were made to have the diameters of 875 μm, 675 μm, and 475 μm, respectively. Other points in Comparative Examples 1 and 2 were the same as in Example 1.

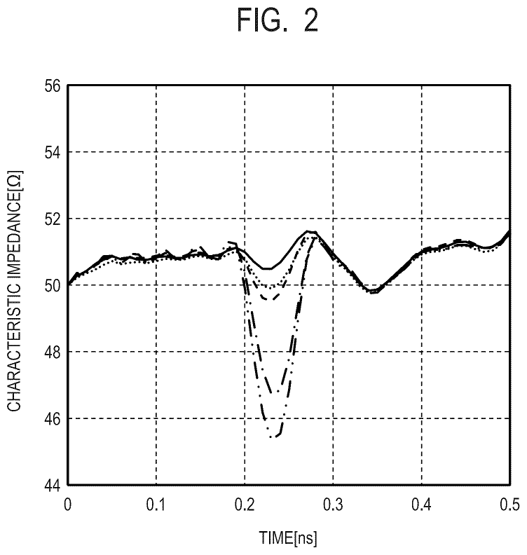

FIG. 2 is a graph showing the simulation results of analyzing the TDR characteristics of Example 1 and Comparative Examples 1 and 2, as well as Examples 2 and 3 described below. In the graph, the vertical axis indicates the characteristic impedance (Ω) and the horizontal axis indicates the time (ns). In the graph, the solid line shows the simulation result of Example 1, the double-dashed line shows the simulation result of Comparative Example 1, and the single-dashed line shows the simulation result of Comparative Example 2. The short-dashed line shows the simulation result of Example 2, and the long-dashed line shows the simulation result of Example 3.

In the graph shown in FIG. 2, the characteristic impedance of the wiring 102 is in the vicinity of the time 0 to 0.2 ns. Further, the time around 0.2 to 0.23 ns is the range where the characteristic impedance is decreased by the via portion including the build-up via 104 and the through-via 105. Further, the characteristic impedance of the wiring 103 is in the vicinity of the time around 0.23 to 0.43 ns. Note that, since the end of the wiring 103 was terminated with a resistance of 50Ω, the waveform continues after the time of 0.43 ns.

As shown in FIG. 2, the minimum value of the characteristic impedance of the via portion of Example 1 was 50.5Ω with respect to the characteristic impedance of the wiring 102 of 51Ω. On the other hand, the characteristic impedance of the via portion decreased to 45.4Ω in Comparative Example 1 and to 46.7Ω in Comparative Example 2. In Example 1, the characteristic impedance fell within a range of 51 Ω±5% (48.45 to 53.55Ω) based on the characteristic impedance of the wiring 102. On the other hand, in Comparative Examples 1 and 2, the characteristic impedance deviated from 51 Ω±5% due to the via portion.

In Example 1, the diameter of the ground clearance 104e of the conductor layer 113 was 875 μm, which was larger than the diameter of 500 μm of the via pad 105b-2 that was the same layer as the conductor layer 114. That is, in Example 1, the ground pattern 113a of the conductor layer 113 did not overlap the via pad 105b of the same layer as the conductor layer 114 in a plan view viewed in a direction perpendicular to the board surface of the printed wiring board 101. Therefore, in the structure including the build-up via 104 and the through via 105 stacked on each other, the distance between the ground pattern 113a of the conductor layer 113 and the via pad 105b-2 of the conductor layer 114 became longer. Therefore, in Example 1, the parasitic capacitance between the ground pattern 113a of the conductor layer 113 and the via pad 105b-2 of the same layer as the conductor layer 114 became smaller, and the impedance mismatch could be suppressed.

On the other hand, in Comparative Examples 1 and 2, the diameter of the ground clearance 104e of the conductor layer 113 was 475 μm with respect to the diameter of 500 μm of the via pad 105b-2 of the same layer as the conductor layer 114. That is, in Comparative Examples 1 and 2, the diameter of the ground clearance 104e with respect to the build-up via 104 was smaller than the diameter of the via pad 105b-2 of the through via 105. Therefore, in Comparative Examples 1 and 2, the ground pattern 113a of the conductor layer 113 overlapped with the via pad 105b-2 of the same layer as the conductor layer 114 in a plan view viewed in a direction perpendicular to the board surface of the printed wiring board 101. Therefore, in the structure including the build-up via 104 and the through via 105 stacked on each other, the distance between the ground pattern 113a of the conductor layer 113 and the via pad 105b-2 of the same layer as the conductor layer 114 became shorter. Therefore, in Comparative Examples 1 and 2, the parasitic capacitance between the ground pattern 113a of the conductor layer 113 and the via pad 105b-2 of the same layer as the conductor layer 114 became larger, and the impedance mismatch could not be suppressed.

### Example 2

In Example 2, the diameter of the ground clearance 104e for the build-up via 104 in Example 1 was changed. That is, in Example 2, the diameter of the ground clearance 104c of the conductor layer 111 was 675 μm. The diameter of the ground clearance 104d of the conductor layer 112 was 775 μm. The diameter of the ground clearance 104e of the conductor layer 113 was 775 μm. Other points in Example 2 were the same as in Example 1.

Similar to the printed wiring board 101 of Example 1, the TDR characteristics of the printed wiring board 101 of Example 2 were analyzed by simulation. In the graph shown in FIG. 2, the short-dashed line indicates the simulation result of Example 2.

As shown in FIG. 2, the minimum value of the characteristic impedance of the via portion of Example 2 was 49.9Ω. In Example 2, the characteristic impedance fell within a range of 51 Ω±5% (48.45 to 53.55Ω) based on the characteristic impedance of the wiring 102.

In Example 2, the diameter of the ground clearance 104e of the conductor layer 113 was 775 μm, which was larger than the diameter of 500 μm of the via pad 105b-2 of the same layer as the conductor layer 114. That is, in Example 2, the ground pattern 113a of the conductor layer 113 and the via pad 105b-2 of the same layer as the conductor layer 114 did not overlap in a plan view viewed in a direction perpendicular to the board surface of the printed wiring board 101. Therefore, in the structure including the build-up via 104 and the through via 105 stacked on each other, the distance between the ground pattern 113a of the conductor layer 113 and the via pad 105b-2 of the same layer as the conductor layer 114 became longer. Therefore, in Example 2, the parasitic capacitance between the ground pattern 113a of the conductor layer 113 and the via pad 105b-2 of the same layer as the conductor layer 114 became smaller, and the impedance mismatch could be suppressed.

### Example 3

In Example 3, the diameters of the ground clearances 104d and 104e for the build-up via 104 in Example 1 were changed. That is, in Example 3, the diameter Dc of the ground clearance 104c of the conductor layer 111 was 675 μm. The diameter Dd of the ground clearance 104d of the conductor layer 112 was 675 μm. The diameter De of the ground clearance 104e of the conductor layer 113 was 775 μm. Other points in Example 3 were the same as in Example 1.

Similar to the printed wiring board 101 of Example 1, the TDR characteristics of the printed wiring board 101 of Example 3 were analyzed by simulation. In the graph shown in FIG. 2, the long-dashed line indicates the simulation result of Example 3.

As shown in FIG. 2, the minimum value of the characteristic impedance of the via portion of Example 3 was 49.5Ω. In Example 3, the characteristic impedance fell within a range of 51 Ω±5% (48.45 to 53.55Ω) based on the characteristic impedance of the wiring 102.

In Example 3, the diameter of the ground clearance 104e of the conductor layer 113 was 775 μm, which was larger than the diameter of 500 μm of the via pad 105b of the same layer as the conductor layer 114. That is, in Example 3, the ground pattern 113a of the conductor layer 113 and the via pad 105b-2 of the same layer as the conductor layer 114 did not overlap in a plan view viewed in a direction perpendicular to the board surface of the printed wiring board 101. Therefore, in the structure including the build-up via 104 and the through via 105 stacked on each other, the distance between the ground pattern 113a of the conductor layer 113 and the via pad 105b-2 of the same layer as the conductor layer 114 became longer. Therefore, in Example 3, the parasitic capacitance between the ground pattern 113a of the conductor layer 113 and the via pad 105b-2 of the same layer as the conductor layer 114 became smaller, and the impedance mismatch could be suppressed.

As is common to Examples 1, 2, and 3, the diameters of the ground clearances 104c, 104d, and 104e are larger than the diameters of the via pad 105b-2 of the same layer as the conductor layer 114, which is a necessary condition for the impedance matching.

Note that the diameters of the ground clearances 104c, 104d, and 104e need not be the diameter of the ground clearance 104e, the diameter of the ground clearance 104d, and the diameter of the ground clearance 104c in descending order of size as in Example 1. As in Examples 2 and 3, there may be ground clearances of the same diameter among the ground clearances 104c, 104d, and 104e. However, when the diameters of the ground clearances 104c and 104d are the same as the diameter of the ground clearance 104e, the distance from the wiring 102 wired in the ground clearance 104c in the conductor layer 111 to the ground increases. As a result, the characteristic impedance of the wiring 102 may increase excessively. Therefore, the diameters of the ground clearances 104c and 104d are preferably smaller than the diameter of the ground clearance 104e. In addition, when the diameters of all the ground clearances in the build-up layer 151 are increased, the area of the region where the components can be arranged becomes smaller. Therefore, it is preferable that the diameters of the outer ground clearances in the build-up layer 151 be smaller.

### Second Embodiment

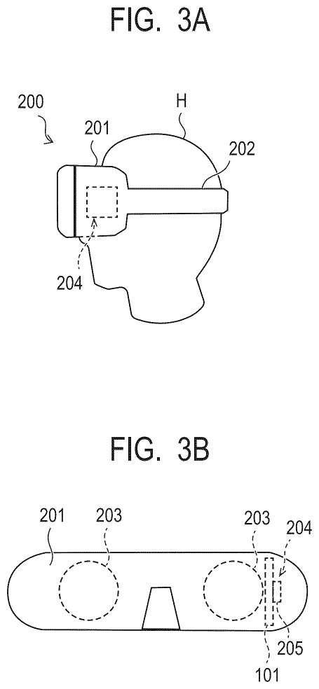

Electronic equipment according to a second embodiment of the present disclosure will be described with reference to FIG. 3A and FIG. 3B. FIG. 3A and FIG. 3B are schematic diagrams illustrating a head-mounted display (TIMID) as an example of the electronic equipment according to the present embodiment. FIG. 3A is a side view of the HMD, and FIG. 3B is a front view of the HMD. Note that the same components as those in the first embodiment are labeled with the same reference numerals and the description thereof will be omitted or simplified. In the present embodiment, the HMD which is a video displaying apparatus will be described as an example of the electronic equipment using the printed wiring board 101 according to the first embodiment. The HMD is used for cross-reality (XR) such as virtual reality (VR), augmented reality (AR), mixed reality (MR), and the like, for example.

As illustrated in FIG. 3A and FIG. 3B, the HMD 200 includes a housing 201, a mounting tool 202, display units 203 for the left eye and right eye, and a control unit 204. Each of the display units 203 and the control unit 204 are housed and arranged in the housing 201. The display units 203 for the left eye and the right eye are display units that display videos or images for the left eye and the right eye, respectively. The control unit 204 is an electronic module that functions as a control unit that controls the operation of the HMD 200 including each of the display units 203 and the like.

The control unit 204 is a printed circuit board that includes the printed wiring board 101 according to the first embodiment and a semiconductor device 205 as a component mounted on the printed wiring board 101. The semiconductor device 205 controls each of the components of the HMID 200 such as the display units 203, and transmits and receives signals such as a video signal, a control signal, and the like by using signal wirings including the wirings 102 and 103 electrically connected through the build-up via 104 and the through via 105 in the printed wiring board 101.

As in the present embodiment, the printed wiring board 101 according to the first embodiment can be used for the HMD 200. In addition to the HMID 200, the printed wiring board 101 according to the first embodiment can be used for electronic equipment such as a computer, a display, video equipment, and the like. In the electronic equipment, the printed wiring board 101 is used as a printed circuit board on which various components such as a semiconductor device are mounted.

According to the present disclosure, the quality of the waveform of the transmission signal in the build-up substrate can be improved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-207282, filed Dec. 7, 2023, which is hereby incorporated by reference herein in its entirety.

What is claimed is:

1. A printed wiring board comprising:
a first layer including a plurality of stacked conductor layers;
a second layer on which the first layer is stacked;
a plurality of first vias formed in the first layer;
a plurality of first pads formed corresponding to the plurality of conductor layers in the first layer and connected to the first vias, respectively;
a plurality of ground patterns formed in the plurality of conductor layers and each having an opening surrounding the first pad;
a second via formed in the second layer; and
a second pad formed on a surface of the second layer on a side of the first layer and connected to the first via and the second via,
wherein the plurality of first pads and the second pad overlap in a plan view viewed in a direction in which the first layer and the second layer are stacked,
wherein the diameters of a plurality of the openings in the plurality of ground patterns are larger than the diameter of the second pad, and
wherein the diameter of the opening farthest from the second layer is smaller than the diameter of the opening closest to the second layer.

2. The printed wiring board according to claim 1, wherein of the plurality of openings, the opening farthest from the second layer has the smallest diameter.

3. The printed wiring board according to claim 1, wherein the diameters of the plurality of openings are smaller the farther the openings are from the second layer.

4. The printed wiring board according to claim 1, wherein the diameters of at least two of the plurality of openings are equal to each other.

5. The printed wiring board according to claim 1, wherein a diameter of the first pad is smaller than a diameter of the second pad.

6. The printed wiring board according to claim 1, wherein a diameter of the first via is smaller than a diameter of the second via.

7. The printed wiring board according to claim 1, wherein the second via is a via that penetrates the second layer.

8. The printed wiring board according to claim 1, comprising a first wiring connected to the first pad surrounded by the opening farthest from the second layer.

9. The printed wiring board according to claim 1, wherein the opening farthest from the second layer is formed in the ground pattern located at an outermost layer of the first layer.

10. The printed wiring board according to claim 1, wherein the second layer is a core layer, and
wherein the second via is a through-via that penetrates the core layer.

11. The printed wiring board according to claim 10, wherein the first layer is a build-up layer stacked on the core layer.

12. The printed wiring board according to claim 1, comprising:
a third pad formed on a side of the second layer opposite to the first layer and connected to the second via; and
a second wiring connected to the third pad.

13. An electronic module comprising:
the printed wiring board according to claim 1; and
a component mounted on the printed wiring board.

14. Electronic equipment comprising:
a housing; and
the electronic module according to claim 13 arranged inside the housing.

15. A video displaying apparatus comprising:
a housing;
a display unit that is arranged inside the housing and displays a video;
the printed wiring board according to claim 1 arranged inside the housing; and
a semiconductor device that is mounted on the printed wiring board and controls the display unit.
